(19) United States
(12) Patent Application Publication
(10) Pub. No.: US 2020/0150195 A1
(43) Pub. Date: May 14, 2020

(54) TWO PIN MAGNETIC FIELD DETECTOR

(71) Applicant: Crocus Technology Inc., Santa Clara, CA (US)

(72) Inventor: Robert D. ZUCKER, Half Moon Bay, CA (US)

(21) Appl. No.: 16/683,749

(22) Filed: Nov. 14, 2019

Related U.S. Application Data
(63) Continuation of application No. 62/767,116, filed on Nov. 14, 2018.

(51) Int. Cl. G01R 33/09

(52) U.S. Cl. CPC G01R 33/09

(57) ABSTRACT

An apparatus includes a magnetic bridge sensor generating an output in response to a sensed magnetic field. An amplification stage processes the output to produce an amplified output signal. A field-effect transistor with a gate receives the amplified output signal, a source node receives a current source and a drain node is connected to the magnetic sensor. A regulator is connected to the magnetic bridge sensor. A first contact is connected to the source node to produce a voltage signal characterizing the sensed magnetic field. A second contact is connected to the magnetic bridge sensor and the regulator.

### CROSS-REFERENCE TO RELATED APPLICATION

This application claims priority to U.S. Provisional Patent Application Ser. No. 62/767,116, filed Nov. 14, 2018, the contents of which are incorporated herein by reference.

### FIELD OF THE INVENTION

This invention relates generally to signal sensing. More particularly, this invention is directed toward a two pin magnetic field detector.

### BACKGROUND OF THE INVENTION

Existing magnetic sensors typically utilize a Hall Sensor, which requires at least four pins or contacts. Accordingly, there is a need for a more compact magnetic field sensor with fewer pins.

### SUMMARY OF THE INVENTION

An apparatus includes a magnetic bridge sensor generating an output in response to a sensed magnetic field. An amplification stage processes the output to produce an amplified output signal. A field-effect transistor with a gate receives the amplified output signal, a source node receives a current source and a drain node is connected to the magnetic sensor. A regulator is connected to the magnetic bridge sensor. A first contact is connected to the source node to produce a voltage signal characterizing the sensed magnetic field. A second contact is connected to the magnetic bridge sensor and the regulator.

### BRIEF DESCRIPTION OF THE FIGURES

The invention is more fully appreciated in connection with the following detailed description taken in conjunction with the accompanying drawings, in which:

FIG. 1 illustrates a two contact magnetic field detector configured in accordance with an embodiment of the invention.

FIG. 2 illustrates a specific circuit configuration to implement the two contact magnetic field detector of FIG. 1.

FIG. 3 illustrates a bandgap reference shunt regulator utilized in accordance with an embodiment of the invention.

Like reference numerals refer to corresponding parts throughout the several views of the drawings.

### DETAILED DESCRIPTION OF THE INVENTION

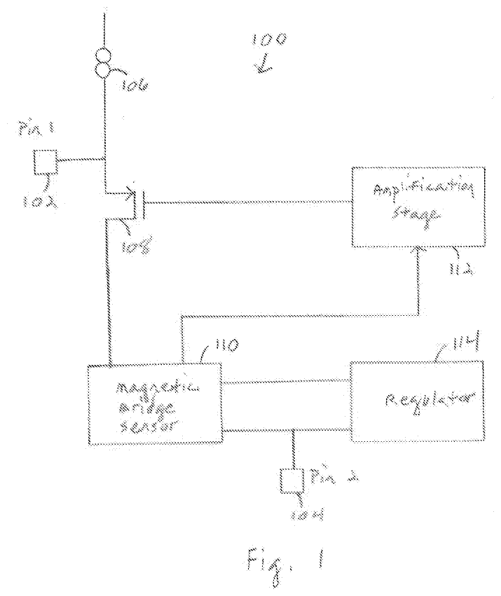

FIG. 1 illustrates a two contact magnetic field detector 100 in accordance with an embodiment of the invention. The detector 100 has a first contact or pin 102 that produces a voltage signal characterizing a sensed magnetic field and a second contact or pin 104, which is a ground contact. The voltage signal characterizing the sensed magnetic field is an analog voltage signal.

An externally generated constant current bias source 106 is connected to a source node of field-effect transistor 108 (e.g., by applying the current bias source 106 to pin 102). A magnetic bridge sensor 110 is connected to the drain of the field-effect transistor 108. In one embodiment, the magnetic bridge sensor 110 is a Tunnel Magneto-Resistance magnetic bridge sensor. The magnetic bridge sensor generates an output in response to a sensed magnetic field. The output is applied to amplification stage 112, which produces an amplified output signal, which is applied to the gate of field-effect transistor 108. A regulator 114 is connected to the magnetic bridge sensor 110.

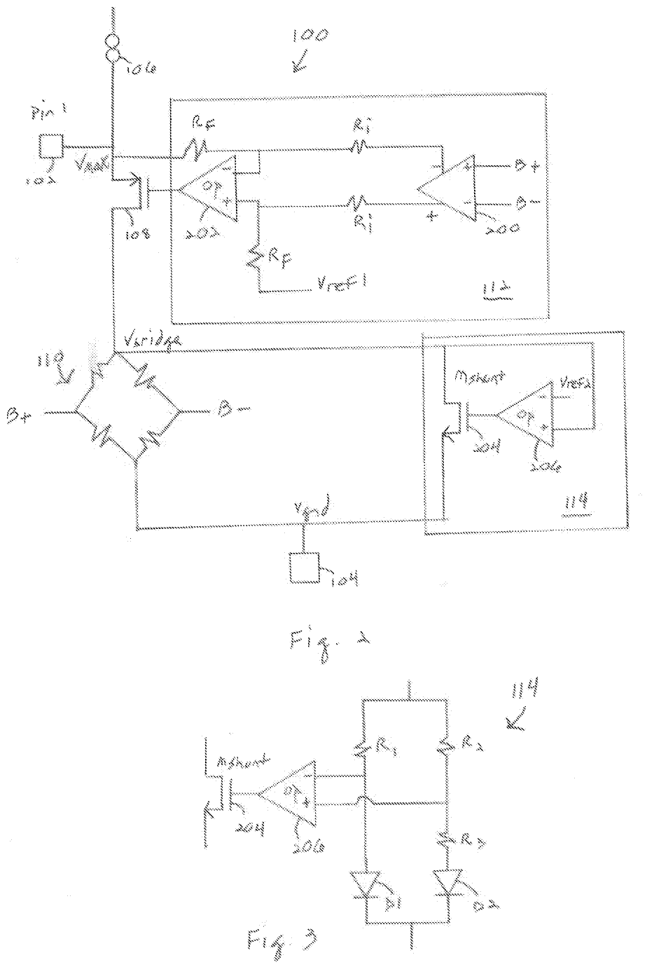

FIG. 2 illustrates that amplification stage 112 may include an instrumentation amplifier 200 to receive the output from the magnetic bridge sensor. The output from instrumentation amplifier 200 drive operational amplifier 202. Operational amplifier 202 also receives a reference voltage Vref1, which is an internally generated signal (i.e., it does not require a pin or contact). The output of operational amplifier 202 drives the gate of field-effect transistor 108. FIG. 2 also illustrates regulator 114 implemented as a shunt regulator with an operational amplifier 206 with one node connected to an internally generated Vref2 signal and another node connected to the magnetic bridge sensor 110. The output of the operational amplifier 206 drives a field-effect transistor 204.

FIG. 3 illustrates that the regulator 114 may be implemented as a bandgap reference shunt regulator with operational amplifier 206 and field-effect transistor 204. The input to the operational amplifier 206 is controlled by bandgap circuitry including resistors R1, R2, R3 and diodes D1, D2.

The circuit 100 of FIG. 2 is operated such that Vref1=Vbridge=Vref2. Field-effect transistor 204 produces current to keep Vbridge regulated to Vref2. All amplifiers may be powered using Vgnd and Vmax. In some cases Vmax may be replaced by a charge pumped supply that can be above Vmax. Vref1 may be connected to Vbridge or for more flexible operation, to a reference voltage that is higher than Vbridge, allowing for bipolar operation.

In FIG. 2, with Vref1=Vbridge, only unipolar operation is possible because the lowest voltage that Vmax can reach is Vbridge. This occurs when the magnetic field is zero or “negative” (B+<B−). For “positive” magnetic fields (B+>B−), the output, Vmax, increases according to the net gain of the instrumentation amplifier 200 multiplied by Rf/Ri. For lower gains given by Rf/Ri, the response at the output pin 102 is approximately linear to the magnetic field, which provides a measurement of the field strength. For sufficiently large gains given by Rf/Ri, the output becomes a comparator that can either detect a change in the magnetic field, according to a predetermined threshold given by the reference voltages, or a change in polarity of the magnetic field.

An alternative embodiment of the invention uses separate references for Vref1, Vref2, and Vbridge. The alternate embodiment may include an internal charge pump to allow for more flexibility, allowing Vmax to go above and below a reference voltage and thus implement bipolar operation, responding to two directions of magnetic field.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. An apparatus, comprising:
a magnetic bridge sensor generating an output in response to a sensed magnetic field;
an amplification stage to process the output to produce an amplified output signal;
a field-effect transistor with a gate to receive the amplified output signal, a source node to receive a current source and a drain node connected to the magnetic sensor;
a regulator connected to the magnetic bridge sensor;
a first contact connected to the source node to produce a voltage signal characterizing the sensed magnetic field; and
a second contact connected to the magnetic bridge sensor and the regulator.

2. The apparatus of claim 1 wherein the magnetic bridge sensor is a Tunnel Magneto-Resistance magnetic bridge sensor.

3. The apparatus of claim 1 wherein the amplification stage includes an instrumentation amplifier and an operational amplifier.

4. The apparatus of claim 1 wherein the regulator is a shunt regulator.

5. The apparatus of claim 1 wherein the regulator is a bandgap reference shunt regulator.
